(19) United States
(12) Patent Application Publication
(10) Pub. No.: US 2013/0186678 A1
(43) Pub. Date: Jul. 25, 2013

(54) SUBSTRATE SET, ELECTRONIC DEVICE, AND METHOD FOR MANUFACTURING SUBSTRATE SET

(71) Applicants: Eiji Koike, Osaka (JP); Yukihiro Sumida, Osaka (JP); Toshiteru Nakawaki, Osaka (JP)

(72) Inventors: Eiji Koike, Osaka (JP); Yukihiro Sumida, Osaka (JP); Toshiteru Nakawaki, Osaka (JP)

(73) Assignee: SHARP KABUSHIKI KAISHA, Osaka (JP)

(21) Appl. No.: 13/578,965

(22) PCT Filed: Jan. 6, 2011
(86) PCT No.: PCT/JP2011/050068

§ 371 Date: Sep. 5, 2012

(30) Foreign Application Priority Data
Feb. 17, 2010 (JP) 2010-032673

(51) Int. Cl. H05K 1/14; H05K 3/00

(52) U.S. Cl. CPC H05K 1/144; H05K 3/00
USPC 174/261; 29/830

(57) ABSTRACT

Provided is a highly accurately alignable substrate set, the cost of which is kept low. In the substrate set, a light source FPC substrate (11) has a notch (16), and an anode pad (13) and a cathode pad (14) that are disposed so as to sandwich the notch (16) therebetween, and a panel FPC substrate (21) has a plus terminal (23) and a minus terminal (24) that are disposed so as to be in contact with the anode pad (13) and the cathode pad (14), and an opening (26) that is sandwiched between the plus terminal (23) and the minus terminal (24).

### TECHNICAL FIELD

The present invention relates to a set of a plurality of substrates (substrate set) that is provided in an electronic device, an electronic device provided with such a substrate set, and a method of manufacturing the substrate set.

### BACKGROUND ART

In an electronic device, conductive members (contact portions) of respective members (substrates, for example) that are electrically connected to each other need to be accurately in contact with each other. In order to satisfy this requirement, various techniques have been devised. In Patent Document 1, for example, conductors 115 of a cable 111 are accurately connected to metal plates 125 of an insulator 121 as shown in a two-side view (a plan view and a cross-sectional view) in FIG. 19.

More specifically, a plurality of projections 127 are formed on the insulator 121, and openings 116 that engage the projections 127 are made in the cable 111. This way, the cable 111 is accurately placed in a desired position on the insulator 121. In other words, the conductors 115 of the cable 111 accurately overlap the metal plates 125 on the insulator 121.

### RELATED ART DOCUMENT

### Patent Document

Patent Document 1: Japanese Patent Application Laid-Open Publication No. H11-187559

### SUMMARY OF THE INVENTION

### Problems to be Solved by the Invention

The projections 127 on the insulator 121, however, are arranged in locations far from the metal plates 125. Thus, in order to secure arrangement space for the projections 127, the insulator 121 needs to have a large area. With reference to this Patent Document 1, a case where a plurality of substrates are stacked and electrically connected to each other is described as an example. That is, a substrate having projections and a substrate having openings that engage the projections are to be stacked, and conductive members in the respective substrates are to be accurately in contact with each other.

In this case, the substrate having the projections needs to have a large area so as to secure arrangement space for the projections, which is likely to cause an increase in the cost of this substrate, and therefore the cost of the substrate set.

The present invention was made in view of the problems described above, and an object of the present invention is to provide a set of substrates that are aligned to each other with a high degree of accuracy without increasing the cost thereof, an electronic device equipped with such a substrate set, and a method of manufacturing the substrate set.

### Means for Solving the Problems

A substrate set including a plurality of substrates that are stacked includes: a first substrate that has a first gap portion and a first contact portion, the first contact portion being disposed so as to sandwich the first gap portion; and a second substrate that has a second contact portion and a second gap portion, the second contact portion being provided to be in contact with the first contact portion, the second gap portion being sandwiched by the second contact portion.

With this configuration, an area around the first contact portion and an area around the second contact portion, which tend to become unutilized areas in the substrates, are utilized as the first gap portion and the second gap portion, respectively, that engage an alignment pin included in a jig set, for example. That is, the unutilized areas in the substrates are effectively utilized. As a result, the areas of the substrates are made smaller, thereby reducing the cost of the substrate set.

It is preferable that the first contact portion be constituted of a group of first contact pieces that are separated from each other, and that the first contact pieces be disposed so as to be divided by the first gap portion. It is preferable that the second contact portion be constituted of a group of second contact pieces that are separated from each other, and that the second contact pieces be disposed so as to be divided by the second gap portion.

It is preferable that when a direction that intersects with a direction in which the first contact pieces are arranged in parallel on a substrate plane of the first substrate is defined as a first intersecting direction, at least one of two ends of the first contact piece in the first intersecting direction be located inside the opposite ends of the first gap portion in the first intersecting direction.

It is preferable that when a direction that intersects with a direction in which the second contact pieces are arranged in parallel on the substrate plane of the second substrate is defined as a second intersecting direction, at least one of two ends of the second contact piece in the second intersecting direction be located inside the opposite ends of the second gap portion in the second intersecting direction.

In any of the above-mentioned configurations, when the two substrate are aligned to each other by the alignment pin engaging the first gap portion and the second gap portion, and when the first contact pieces and the second contact pieces are electrically connected to each other by a bonding material such as solder, for example, the alignment pin blocks the melting solder, thereby preventing the first contact pieces from being electrically connected to each other through the solder and preventing the second contact pieces from being electrically connected to each other through the solder.

When the alignment pin of the jig engages the first gap portion and the second gap portion, for example, it is preferable that these gap portions be linear or polygonal openings, or liner or polygonal notches. This way, the substrates are prevented from turning.

Provided herein is also a substrate set that includes a plurality of substrates that are stacked without using a jig for alignment as described above. Such a substrate set includes a first substrate that has a first gap portion and a first contact portion, the first contact portion being disposed so as to sandwich the first gap portion, and a second substrate that has a second contact portion and a projection, the second contact portion being disposed to be in contact with the first contact portion, the projection being provided so as to engage the first gap portion and so as to be sandwiched by the second contact portion, for example.

With this configuration, an area around the first contact portion and an area around the second contact portion, which tend to become unutilized areas in the substrates, are effectively utilized as arrangement space for the first gap portion and the projection engaging each other. As a result, the areas of the substrates are made smaller, thereby reducing the size and the cost of the substrate set.

It is preferable that the first contact portion be constituted of a group of first contact pieces that are separated from each other, and that the first contact pieces be disposed so as to be divided by the first gap portion. It is preferable that the second contact portion be constituted of a group of second contact pieces that are separated from each other, and that the second contact pieces be disposed so as to be divided by the projection.

It is preferable that when a direction that intersects with a direction in which the first contact pieces are arranged in parallel on a substrate plane of the first substrate is defined as a first intersecting direction, two ends of at least one of the first contact pieces in the first intersecting direction be located inside the opposite ends of the first gap portion in the first intersecting direction.

It is preferable that when a direction that intersects with a direction in which the second contact pieces are arranged in parallel on a substrate plane of the second substrate is defined as a second intersecting direction, two ends of at least one of the second contact pieces in the second intersecting direction be located inside the opposite ends of the projection in the second intersecting direction.

In any of the above-mentioned configurations, when the two substrate are aligned to each other by the projection engaging the first gap portion, and when the first contact pieces and the second contact pieces are electrically connected by a bonding material such as solder, the projection blocks the melting solder, thereby preventing the first contact pieces from being electrically connected to each other through the solder and preventing the second contact pieces from being electrically connected to each other through the solder.

It is preferable that the first gap portion be a linear or polygonal opening, or a linear or polygonal notch, and an outer shape of the projection that engages the first gap portion preferably coincides with a shape of the first gap portion. This way, the substrate is prevented from turning.

It is preferable that the projection be made of an insulating member so as to prevent the first contact pieces from being electrically connected to each other through the solder and so as to prevent the second contact pieces from being electrically connected to each other through the solder.

It is preferable that the projection be a part of a reinforcing member included in the second substrate. As described, if the projection is formed utilizing the reinforcing member that has been conventionally used, it becomes unnecessary to use a special member and the like for the projection. This leads to a reduction in the cost of the substrate set.

The reinforcing member is attached to a substrate sheet that is used as a base of the second substrates and that has an area for the plurality of second substrates to be arranged in parallel. It is preferable that the reinforcing member overlap at least part of an edge of the second substrate in the substrate sheet, and bridge over the plurality of second substrates in the substrate sheet.

With this configuration, a manufacture of the second substrate in the substrate set is simplified.

An electronic device that includes such a substrate set is included in the present invention.

Below is an example of a method of manufacturing such a substrate set, which is a method of manufacturing a substrate set in which a plurality of substrates are at least partially overlapped with each other by using a jig, for example. In such a manufacturing method, the jig includes an alignment pin. The manufacturing method includes placing, on jig fixture, a first substrate that has a first gap portion that engages the alignment pin and a first contact portion disposed so as to sandwich the first gap portion, and stacking the first substrate and a second substrate that has a second gap portion that engages the alignment pin and a second contact portion that is disposed so as to sandwich the second gap portion and so as to cover the first contact portion.

Another example of the method of manufacturing the substrate set includes stacking the first substrate and the second substrate, the first substrate having a first gap portion and a first contact portion disposed so as to sandwich the first gap portion, the second substrate having a second contact portion disposed so as to be in contact with the first contact portion and a projection that engages the first gap portion and that is disposed so as to be sandwiched by the second contact portion.

### Effects of the Invention

According to the present invention, the areas around the respective contact portions (the first contact portion and the second contact portion) that tend to become unutilized areas in the substrate set can be utilized as portions necessary for aligning the substrates. This eliminates a need to separately provide portions for alignment at locations far from the contact portions, for example, thereby reducing the size of the substrates. As a result, the size and the cost of the substrate set are reduced.

### BRIEF DESCRIPTION OF THE DRAWINGS

FIG. 1 is an exploded perspective view of a liquid crystal display device and of a substrate set that is Example 1.

FIG. 2 is a perspective view showing a liquid crystal display panel, a backlight unit, and a jig (Example 1).

FIG. 3 is a perspective view enlarging a panel FPC substrate included in the liquid crystal display panel, a light source FPC substrate included in the backlight unit, and the jig (Example 1).

FIG. 4 is a plan view of the panel FPC substrate included in the liquid crystal display panel and the light source FPC substrate included in the backlight unit (Example 1).

FIG. 5 is a plan view enlarging FIG. 4 (Example 1).

FIG. 6 is a plan view of the panel FPC substrate included in the liquid crystal display panel and the light source FPC substrate included in the backlight unit (Comparative Example 1).

FIG. 7 is a plan view showing a substrate set of Example 2.

FIG. 8 is an exploded perspective view of the liquid crystal display device and of a substrate set of Example 3.

FIG. 9 is a perspective view enlarging the panel FPC substrate included in the liquid crystal display panel and the light source FPC substrate included in the backlight unit (Example 3).

FIG. 10 is a plan view of the panel FPC substrate included in the liquid crystal display panel and the light source FPC substrate included in the backlight unit (Example 3).

FIG. 11 is a plan view enlarging FIG. 10 (Example 3).

FIG. 12 is a plan view showing a substrate set of Example 4.

FIG. 13 is a plan view showing a substrate sheet in a workable size.

FIG. 14 is an enlarged perspective view of the panel FPC substrate included in the liquid crystal display panel and the light source FPC substrate included in the backlight unit (Example 5).

FIG. 15 is a cross-sectional view along the line A-A′ indicated by arrows in FIG. 14 (Example 5).

FIG. 16 is a plan view of the panel FPC substrate included in the liquid crystal display panel and the light source FPC substrate included in the backlight unit (Example 5).

FIG. 17 is a plan view of the panel FPC substrate included in the liquid crystal display panel and the light source FPC substrate included in the backlight unit (Example 6).

FIG. 18 is a plan view of the panel FPC substrate included in the liquid crystal display panel and the light source FPC substrate included in the backlight unit (Comparative Example 2).

FIG. 19 is a two-side view, which is a side view and a cross-sectional view, showing a conventional insulator and a cable being electrically connected.

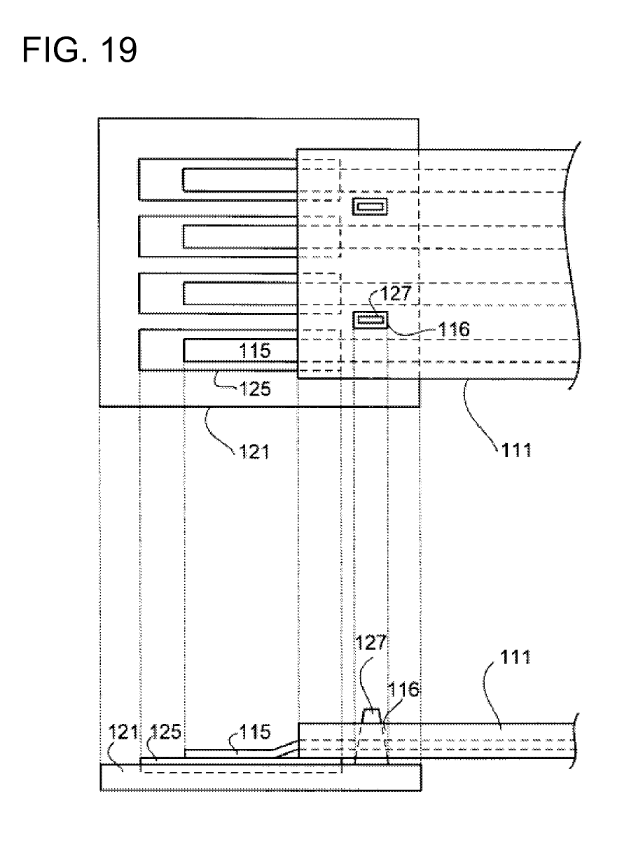

### DETAILED DESCRIPTION OF EMBODIMENTS

### Embodiment 1

An embodiment will be described below with reference to figures. Hatching, reference characters for components, and the like may be omitted for convenience, and in that case, other figures are to be referred to. Hatching may also be used in a plan view and the like. Further, wiring lines formed on substrates are omitted for convenience, and lines of members that overlap each other may be illustrated so as to be offset with each other for ease of reference. Furthermore, an opening formed in a substrate, which will be described later, may be colored for ease of reference.

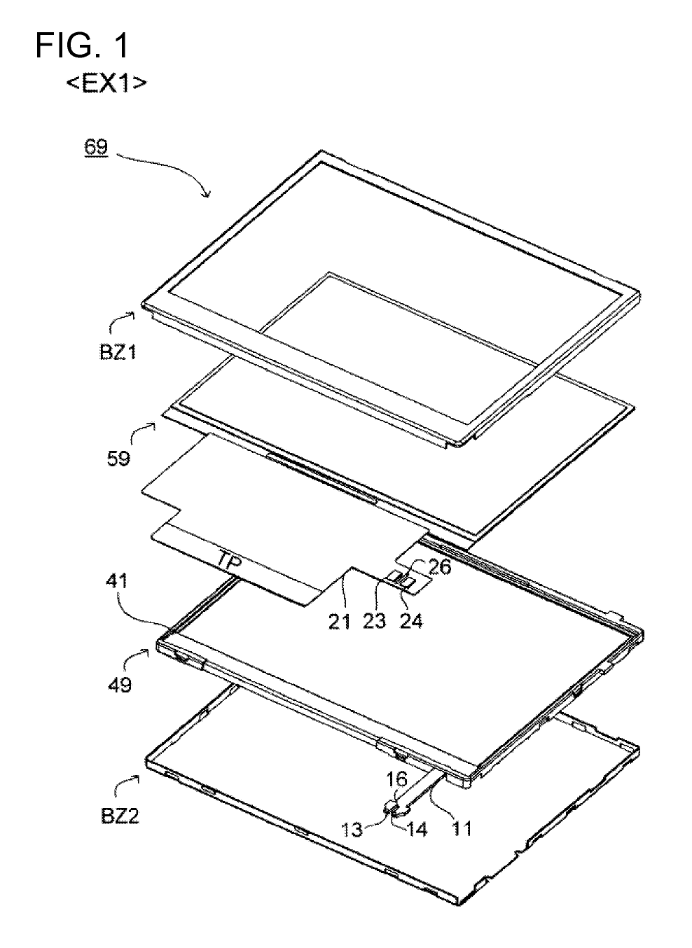

A perspective view in FIG. 1 is an exploded perspective view of a liquid crystal display device 69 that is an example of an electronic device. The liquid crystal display device 69 includes a backlight unit (illumination device) 49 that emits planar light, a non-light-emitting liquid crystal display panel (display panel) 59 that displays an image by receiving the planar light, and bezels BZ1 and BZ2 that sandwich the backlight unit and the display panel therebetween. Here, the liquid crystal display device 69 shown in FIGS. 1 to 4 and various members included in the liquid crystal display device 69 are referred to as Example 1 (EX1).

An FPC (Flexible Printed Circuit) substrate 11 having not-shown LEDs (Light Emitting Diodes) and the like as a light source mounted thereon is attached to the backlight unit 49. An FPC substrate 21 having not-shown various circuit elements mounted thereon is attached to the liquid crystal display panel 59. (Here, for convenience, the FPC substrate 11 that is attached to the backlight unit 49 is referred to as a light source FPC substrate 11, and the FPC substrate 21 that is attached to the liquid crystal display panel 59 is referred to as a panel FPC substrate 21.)

The light source FPC substrate 11 is connected to the panel FPC substrate 21 so as to establish an electrical connection therebetween. On the light source FPC substrate 11, an anode pad (first contact portion, first contact piece) 13 that is connected to the anode of the LED through wiring, for example, and a cathode pad (first contact portion, first contact piece) 14 that is connected to the cathode of the LED through wiring, for example, are formed.

On the other hand, on the panel FPC substrate 21, wiring for supplying a current from a power source (not shown) is formed, and terminals 23 and 24 that are electrically connected to the wiring are also formed. More specifically, a plus terminal 23 that is to be electrically connected to the anode pad 13 and a minus terminal 24 that is to be electrically connected to the cathode pad 14 are formed.

That is, the plus terminal (second contact portion, second contact piece) 23 is connected to the anode pad 13, and the minus terminal (second contact portion, second contact piece) 24 is connected to the cathode pad 14, thereby establishing the electrical connection between the light source FPC substrate 11 and the panel FPC substrate 21. As a result, the current from the power source (not shown) flows to the LEDs.

As shown in FIG. 1, the light source FPC substrate 11 has a linear portion, and at the end of the linear portion, a notch (first gap portion) 16 is formed. The anode pad 13 and the cathode pad 14 are disposed so as to sandwich the notch 16. On the other hand, an opening (second gap portion) 26 is formed on the panel FPC substrate 21. The plus terminal 23 and the minus terminal 24 are disposed so as to sandwich the opening 26. (Here, at least part of the inner edge shape of the notch 16 and at least part of the inner edge shape of the opening 26 coincide with each other.)

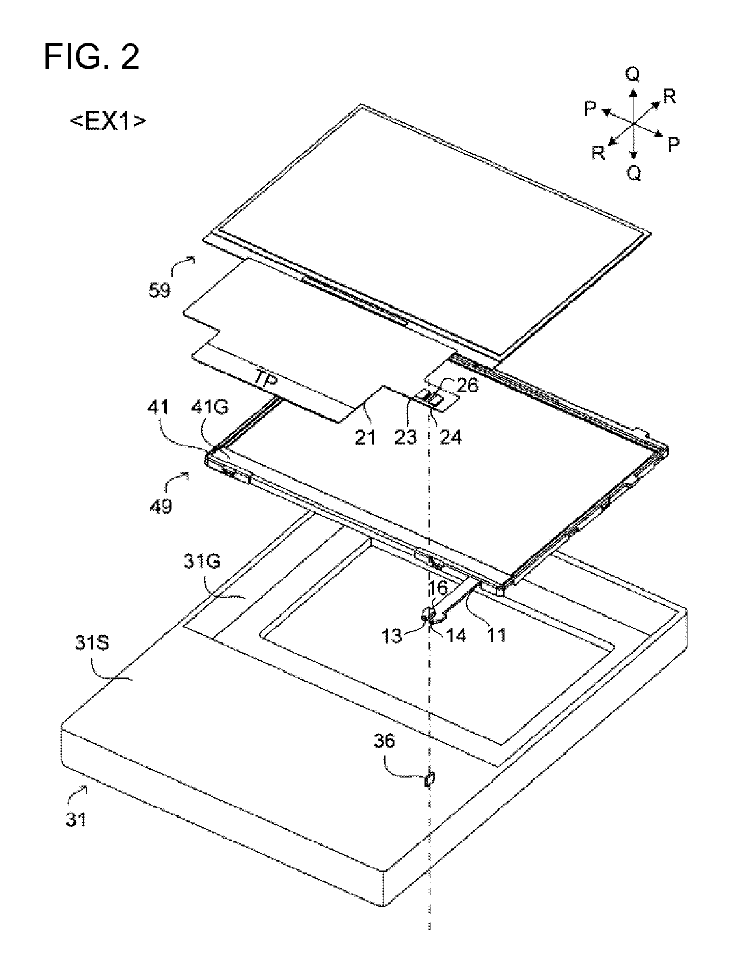

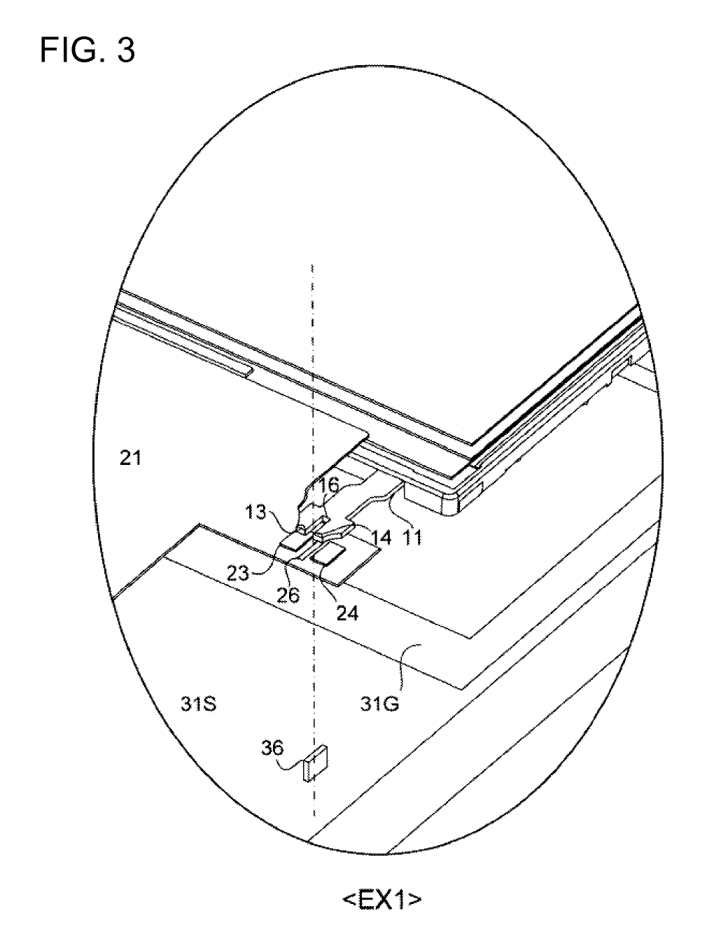

A method of connecting the light source FPC substrate 11 and the panel FPC substrate 21 so as to establish the electrical connection therebetween will be described with reference to FIGS. 2 and 3. As shown in FIG. 2, a jig 31 is used for electrically connecting the light source FPC substrate 11 to the panel FPC substrate 21.

More specifically, first, the liquid crystal display panel 59 is placed on the backlight unit 49, and the liquid crystal display panel 59 is supported by edges of a backlight chassis 41 that constitutes an outer frame of the backlight unit 49. On the edges of the backlight chassis 41, a recess 41G is formed, and the liquid crystal display panel 59 engages the frame-shaped recess 41G. This way, the liquid crystal display panel 59 is affixed to the backlight unit 49.

Thereafter, as shown in FIG. 3, the position of the light source FPC substrate 11 is switched with the position of the panel FPC substrate 21. In other words, when the liquid crystal display panel 59 and the backlight unit 49 are stacked and affixed to each other, the light source FPC substrate 11 included in the backlight unit 49 is located below the panel FPC substrate 21 included in the liquid crystal display panel 59, but the respective positions of the FPC substrates 11 and 21 are to be switched. The switching of the positions can be performed with ease because the light source FPC substrate 11 and the panel FPC substrate 21 are flexible substrates. By bending the linear-shaped light source FPC substrate 11, for example, the light source FPC substrate 11 can be positioned above the panel FPC substrate 21, thereby covering the panel FPC substrate 21 with ease.

Thereafter, the liquid crystal display device 69 described above is fixed to the jig 31. More specifically, the jig 31 has a recess 31G that engages the liquid crystal display device 69, and by placing the liquid crystal display device 69 in the recess 31G, the liquid crystal display device 69 is affixed to the jig. Moreover, on a top surface 31S next to the recess 31G in the jig 31, an alignment pin 36 having an insulation property is formed in an area covered by the light source FPC substrate 11 and the panel FPC substrate 21 overlapping each other.

The shape of the outer periphery of the alignment pin 36 (shape of the outer surface of the pin axis) coincides with the inner edge shape of the notch 16 and the inner edge shape of the opening 26. Thus, the alignment pin 36 engages the opening 26 of the panel FPC substrate 21, and further, the alignment pin 36 that projects from the panel FPC substrate 21 engages the notch 16 of the light source FPC substrate 11. (That is, the alignment pin 36 engages the opening 26 and the notch 16.)

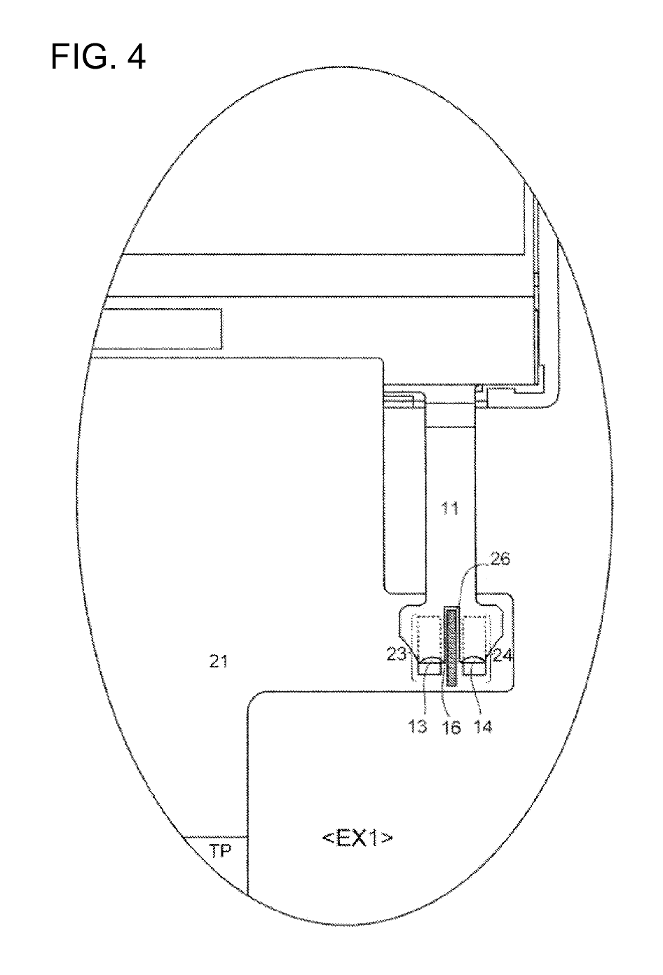

The terminals (13, 14, 23, 24) are designed such that, when the panel FPC substrate 21 and the light source FPC substrate 11 are stacked on the top surface 31S of the jig 31 as described above, the anode pad 13 of the light source FPC substrate 11 overlaps the plus terminal 23 of the panel FPC substrate 21 and the cathode pad 14 of the light source FPC substrate 11 overlaps the minus terminal 24 of the panel FPC substrate 21. Specifically, as shown in a plan view of FIG. 4 (the jig 31 is omitted for convenience), the anode pad 13 and the cathode pad 14 are formed at the end of the light source FPC substrate 11, and the plus terminal 23 and the minus terminal 24 are located immediately below the pads 13 and 14, respectively.

The plus terminal 23 includes an area that is not covered by the light source FPC substrate 11 and that overlaps a part of the outer edge of the light source FPC substrate 11, which also is an end of the anode pad 13. The minus terminal 24 includes an area that is not covered by the light source FPC substrate 11 and that overlaps a part of the outer edge of the light source FPC substrate 11, which also is an end of the cathode pad 14. This allows the anode pad 13 and the plus terminal 23 to be visible at the same time, and allows the cathode pad 14 and the minus terminal 24 to be visible at the same time.

When a bonding material such as a solder, for example, is applied to a border of the anode pad 13 and the plus terminal 23 (end of the anode pad 13 supported by the plus terminal 23) from the side to which the pads and the terminals are exposed (in other words, from the side of the substrate surface of the panel FPC substrate 21 that supports the light source FPC substrate 11), the anode pad 13 and the plus terminal 23 are electrically connected. In the same way, by applying a bonding material such as a solder to a border between the cathode pad 14 and the minus terminal 24 (end of the cathode pad 14 supported by the minus terminal 24), the cathode pad 14 and the minus terminal 24 are electrically connected.

That is, the light source FPC substrate 11 has the notch 16 and the anode pad 13 and the cathode pad 14 disposed so as to sandwich the notch 16. The panel FPC substrate 21 has the plus terminal 23 and the minus terminal 24, which are to be respectively in contact with the anode pad 13 and the cathode pad 14, and the opening 26 that is sandwiched by the plus terminal 23 and the minus terminal 24. This way, the FPC substrates 11 and 21, which overlap each other, are electrically connected without using connectors and the like. (In other words, the cost of connecters can be eliminated.)

The notch 16 is arranged between the anode pad 13 and the cathode pad 14, and the opening 26 is arranged between the plus terminal 23 and the minus terminal 24. This way, the respective areas of the light source FPC substrate 11 and the panel FPC substrate 21 are reduced.

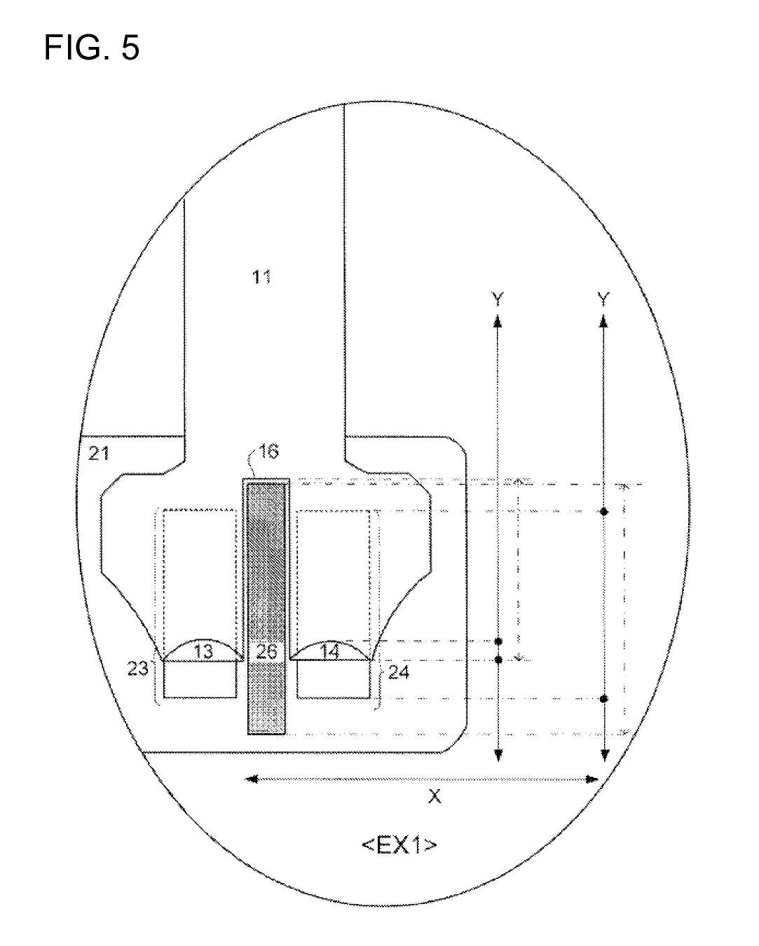

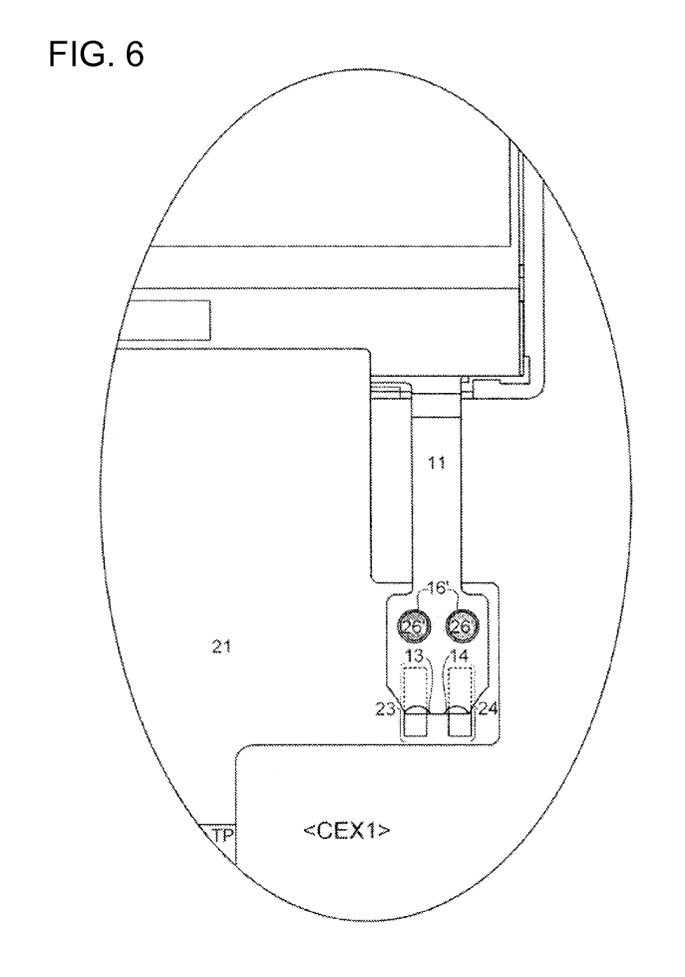

As shown in a plan view in FIG. 6 (Comparative Example 1 (CEX1)), for example, when the anode pad 13 and the cathode pad 14 are formed at the end of the light source FPC substrate 11, and alignment openings 16′ are formed remote from the pads 13 and 14, instead of between the two pads 13 and 14, the area of the light source FPC substrate 11 becomes larger than that of the light source FPC substrate 11 shown in FIG. 5, which is an enlarged view of FIG. 4. (In other words, the light source FPC substrate 11 needs to have an area for having the alignment openings 16′ therein.)

Also, as shown in the plan view in FIG. 6, when the plus terminal 23 and the minus terminal 24 are formed on the panel FPC substrate 21, and alignment openings 26′ are formed remote from the terminals 23 and 24, instead of between the terminals 23 and 24, the area of the panel FPC substrate 21 becomes larger than that of the panel FPC substrate 21 shown in FIG. 5. (In other words, the panel FPC substrate 21 needs to have an area for having the alignment openings 26′ therein.)

That is, in the light source FPC substrate 11, the notch 16 is formed in an area between the anode pad 13 and the cathode pad 14 (area that was not processed in the conventional configuration; an unutilized area). Also, in the panel FPC substrate 21, the opening 26 is formed in an unutilized area between the plus terminal 23 and the minus terminal 24. This way, the limited areas in the FPC substrates 11 and 21 are effectively utilized. As a result, the areas of the FPC substrates 11 and 21 are reduced, thereby reducing the cost of the FPC substrates 11 and 21 and further reducing the cost of the backlight unit 49 and the liquid crystal display device 69.

The anode pad 13 and the cathode pad 14 formed on the light source FPC substrate 11 are separated from each other by the notch 16. The plus terminal 23 and the minus terminal 24 formed on the panel FPC substrate 21 are separated from each other by the opening 26.

With this configuration, the alignment pin 36 of the jig 31 that engages the opening 26 and the notch 16 and that projects from the FPC substrates 11 and 21 serves as a wall to separate the anode pad 13 and the cathode pad 14 and as a wall to separate the plus terminal 23 and the minus terminal 24.

When the anode pad 13 and the plus terminal 23 are electrically connected to each other by a solder, for example, the alignment pin 36 makes it difficult for the solder to make contact with the cathode pad 14 and the minus terminal 24. In other words, the alignment pin 36 blocks the solder that connects the anode pad 13 to the plus terminal 23 from reaching the cathode pad 14 and the minus terminal 24. As a result, the electrical connection between the FPC substrates 11 and 21 is reliably established with ease.

Particularly, it is preferable that the arrangement of the notch 16, the anode pad 13, and the cathode pad 14 on the light source FPC substrate 11 be as shown in FIG. 5. Here, a direction in which the anode pad 13 and the cathode pad 14 are arranged in parallel on the substrate plane of the light source FPC substrate 11 is defined as a direction X, and a direction that intersects with the direction X (at a right angle or the like) is defined as a direction Y.

More specifically, it is preferable that the two ends of the anode pad 13 and the two ends of the cathode pad 14 (see black dots) in the direction Y (first intersecting direction), which is a direction parallel with a line separating the anode pad 13 and the cathode pad 14, be located inside the opposite ends of the notch 16 in the direction Y (see a one-dot chain line in FIG. 5). That is, it is preferable that the notch 16 be formed such that a side of the anode pad 13 between both ends thereof in the direction Y entirely faces the notch 16 in the direction X and such that a side of the cathode pad 14 between both ends thereof in the direction Y entirely faces the notch 16 in the direction X.

This way, the alignment pin 36 engaging the notch 16 can serve as a wall that reliably separates the anode pad 13 and the cathode pad 14, which prevents the solder from making contact with both of the pads 13 and 14 so as to bridge over the two.

It is preferable that the arrangement of the opening 26, the plus terminal 23, and the minus terminal 24 on the panel FPC substrate 21 be similar to that of the notch 16, the anode pad 13, and the cathode pad 14 on the light source FPC substrate 11 as shown in FIG. 5. Here, a direction in which the plus terminal 23 and the minus terminal 24 are arranged in parallel on the substrate plane of the panel FPC substrate 21 is the same as the direction X, and a direction that intersects with the direction X (at a right angle, for example) is defined as a direction Y.

More specifically, it is preferable that the two ends of the plus terminal 23 and the two ends of the minus terminal 24 (see black dots) on the panel FPC substrate 21 in the direction Y (second intersecting direction), which is a direction parallel with a line separating the plus terminal 23 and the minus terminal 24, be located inside the opposite ends of the opening 26 in the direction Y (see a two-dot chain line in FIG. 5). That is, it is preferable that the opening 26 be formed such that a side of the plus terminal 23 between both ends thereof in the direction Y entirely faces the opening 26 in the direction X and such that a side of the minus terminal 24 between both ends thereof in the direction Y entirely faces the opening 26 in the direction X.

This way, the alignment pin 36 engaging the opening 26 can serves as a wall that reliably separates the plus terminal 23 and the minus terminal 24, which prevents the solder from making contact with the terminals 23 and 24 so as to bridge over the two.

It is preferable that the notch 16 in the light source FPC substrate 11 be a linear or polygonal notch. Similarly, it is preferable that the opening 26 on the panel FPC substrate 21 be a linear or polygonal opening. (It is apparent that the outer shape of the alignment pin 36 is linear or polygonal so as to coincide with the notch 16 and the opening 26.)

With this configuration, the alignment pin 36 engages the single notch 16 and the single opening 26, thereby preventing the light source FPC substrate 11 and the panel FPC substrate 21 from turning. (That is, the panel FPC substrate 21 and the light source FPC substrate 11 do not turn with respect to the jig 31.) This means that even if the number of the notch 16 and the opening 26 is reduced to a minimum, the light source FPC substrate 11 and the panel FPC substrate 21 can be prevented from turning. Therefore, the respective areas for forming the notch 16 and the opening 26 in the FPC substrates 11 and 21 are made smaller compared to the areas thereof in the case of forming a number of notches 16 and openings 26 in the FPC substrates 11 and 21.

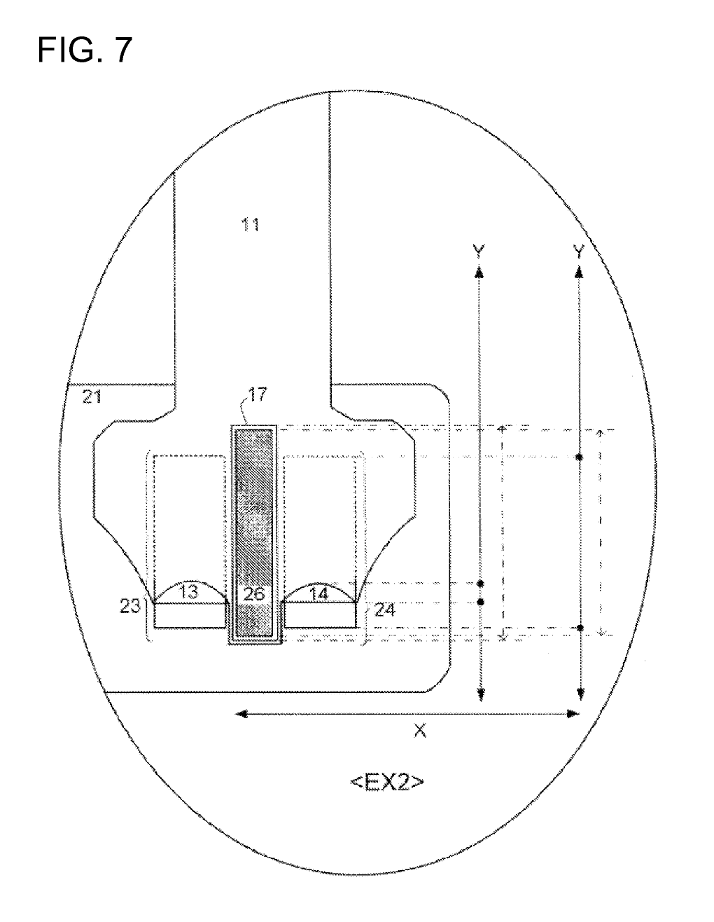

In the configuration described above, the notch 16 and the opening 26 are respectively provided in the light source FPC substrate 11 and in the panel FPC substrate 21 as portions that make contact with the alignment pin 36 of the jig 31. However, the configuration is not limited to such. As shown in a plan view in FIG. 7 (Example 2), for example, the opening 26 may be formed in the panel FPC substrate 21, and an opening 17, instead of the notch 16, may be formed in the light source FPC substrate 11. Alternatively, the notch 16 may be formed in the light source FPC substrate 11, and a notch, instead of the opening 26, may be formed in the panel FPC substrate 21.

That is, portions in the FPC substrates 11 and 21 that make contact with the alignment pin 36 of the jig 31 may be openings or notches. As long as the portions in the FPC substrates 11 and 21 that make contact with the alignment pin 36 of the jig 31 can prevent a displacement (turning or moving) of the FPC substrates 11 and 21 to the jig 31, the portion may be the opening 26, the notch 16, or other structures (a projection, for example).

In a method of manufacturing the substrate set in which the plurality of FPC substrates 11 and 21 are at least partially overlapped with each other by using the jig 31 that includes the alignment pin 36 as described above, stacking steps described below are performed. There is no special limitation on other steps.

More specifically, it is preferable that the method of manufacturing the substrate set include placing the light source FPC substrate 11 on the jig 31 and stacking the panel FPC substrate 21 on the light source FPC substrate 11 (stacking steps). The light source FPC substrate 11 has the notch 16 that engages the alignment pin 36 and the pads 13 and 14 disposed thereon so as to sandwich the notch 16. The panel FPC substrate 21 has the opening 26 that engages the alignment pin 36 and the terminals 23 and 24 disposed thereon so as to sandwich the opening 26 and respectively overlap the pads 13 and 14.

### Embodiment 2

Embodiment 2 will be described below. Members having the same functions as those of the members described in Embodiment 1 are provided with the same reference characters, and descriptions thereof are omitted.

In Embodiment 1, a set of the light source FPC substrate 11 and the panel FPC substrate 21 (this is referred to as a substrate set) is electrically connected using the jig 31. However, the light source FPC substrate 11 and the panel FPC substrate 21 can be electrically connected without using the jig 31.

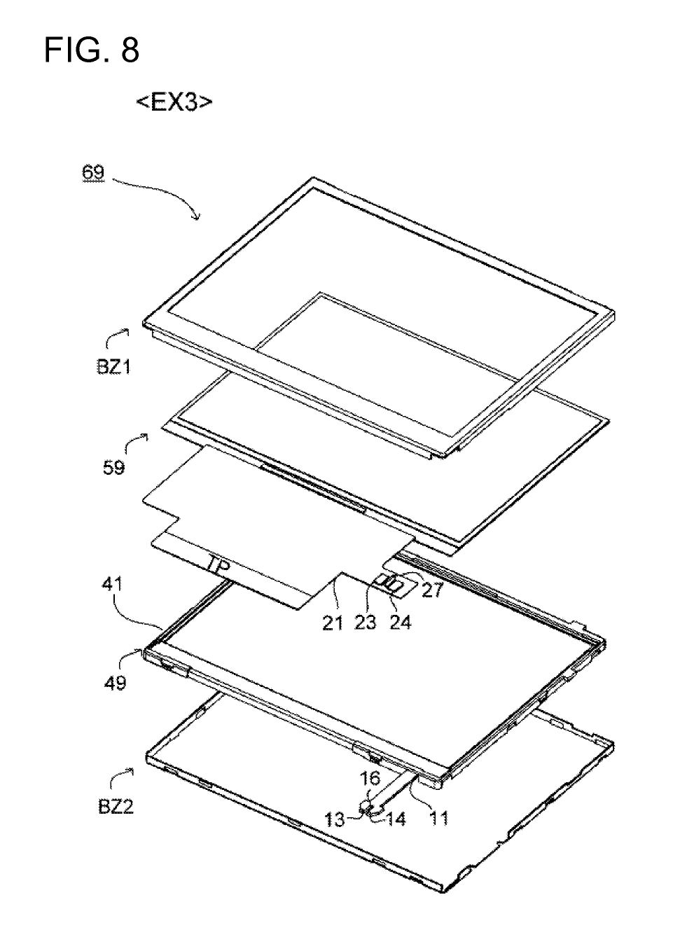

As shown in a perspective view in FIG. 8 (Example 3), for example, the light source FPC substrate 11 is the same as the light source FPC substrate 11 in Example 1 shown in FIG. 1, but the panel FPC substrate 21 is provided with a projection 27, instead of the opening 26. The projection 27 is formed in a shape that fits in the notch 16 of the light source FPC substrate 11. That is, the outer shape of the projection 27 (outer shape of the axis in a direction in which the projection 27 extends) coincides with the inner edge shape of the notch 16.

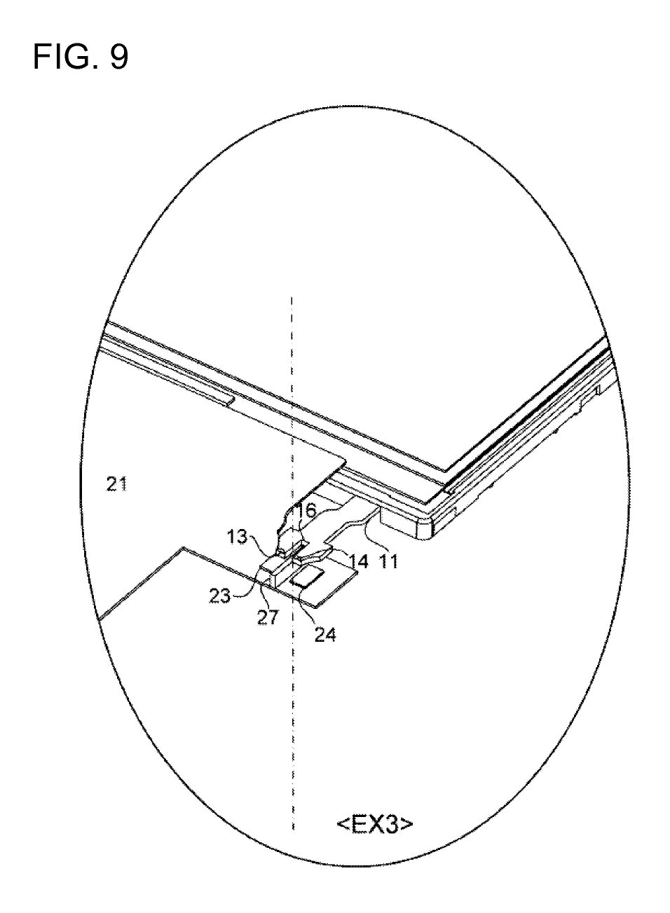

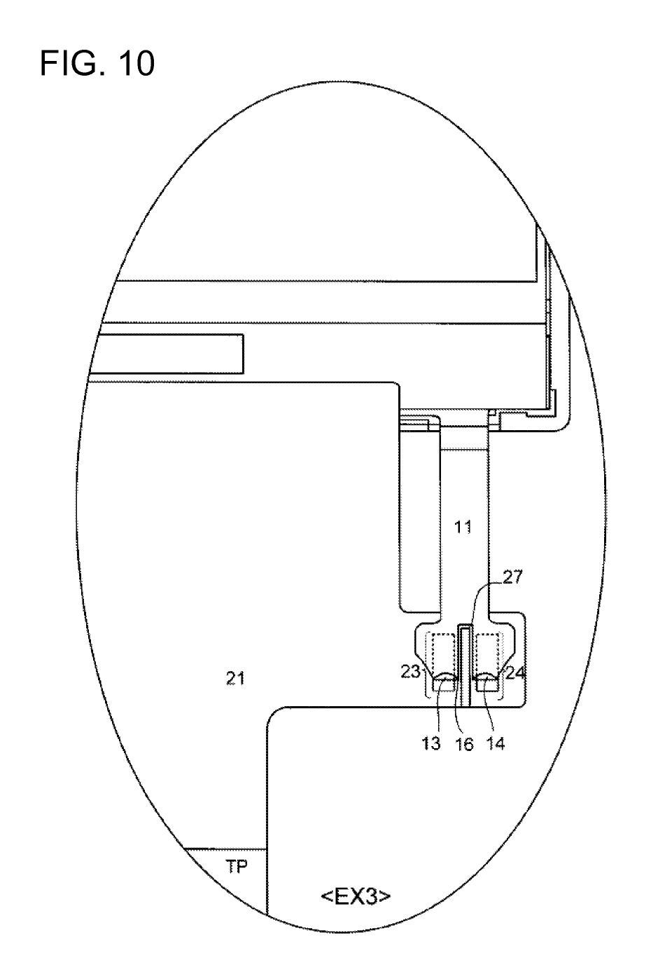

As shown in FIG. 9, the light source FPC substrate 11 included in the backlight unit 49 is placed above the panel FPC substrate 21 included in the liquid crystal display panel 59. Thereafter, the notch 16 of the light source FPC substrate 11 engages the projection 27 of the panel FPC substrate 21. In the same manner as Embodiment 1, the terminals (13, 14, 23, 24) are designed such that the anode pad 13 of the light source FPC substrate 11 overlaps the plus terminal 23 of the panel FPC substrate 21 and such that the cathode pad 14 of the light source FPC substrate 11 overlaps the minus terminal 24 of the panel FPC substrate 21 when the panel FPC substrate 21 and the light source FPC substrate 11 overlap each other (see FIG. 10).

When a solder, for example, is applied to the border between the anode pad 13 and the plus terminal 23 from the side of the substrate surface of the panel FPC substrate 21 that supports the light source FPC substrate 11 in the same manner as Embodiment 1, the anode pad 13 and the plus terminal 23 are electrically connected. When a solder is applied to the border between the cathode pad 14 and the minus terminal 24, the cathode pad 14 and the minus terminal 24 are electrically connected.

In other words, the light source FPC substrate 11 has the notch 16, and is provided with the anode pad 13 and the cathode pad 14 disposed so as to sandwich the notch 16, and the panel FPC substrate 21 is provided with the plus terminal 23 and the minus terminal 24, which are disposed so as to respectively make contact with the anode pad 13 and the cathode pad 14, and the projection 27 that engages the notch 16 and that is sandwiched by the plus terminal 23 and the minus terminal 24. This way, the stacked FPC substrates 11 and 21 are electrically connected to each other without using connectors and the like.

With this configuration, by forming the notch 16 in an unutilized area between the anode pad 13 and the cathode pad 14 in the light source FPC substrate 11, and by forming the projection 27 in an unutilized area between the plus terminal 23 and the minus terminal 24 in the panel FPC substrate 21, limited areas in the FPC substrates 11 and 21 are effectively utilized. Therefore, as in Embodiment 1, the areas of the FPC substrates 11 and 21 are made smaller. In addition, because the jig 31 is not used in electrically connecting the FPC substrates 11 and 21, the connecting step can be performed with ease. (Also, because the jig 31 is eliminated, the manufacturing cost can be further reduced.)

The anode pad 13 and the cathode pad 14 formed on the light source FPC substrate 11 are separated by the notch 16. The plus terminal 23 and the minus terminal 24 formed on the panel FPC substrate 21 are separated by the projection 27.

With this configuration, the projection 27 that engages the notch 16 projects from the FPC substrates 11 and 21, and this projection 27 serves as a wall to separate the anode pad 13 and the cathode pad 14 and as a wall to separate the plus terminal 23 and the minus terminal 24. This way, the projection 27 blocks the solder that connects the anode pad 13 to the plus terminal 23 from reaching the cathode pad 14 and the minus terminal 24 (in other words, a solder bridge is not formed). As a result, as in Embodiment 1, the electrical connection between the FPC substrates 11 and 21 can be reliably established with ease.

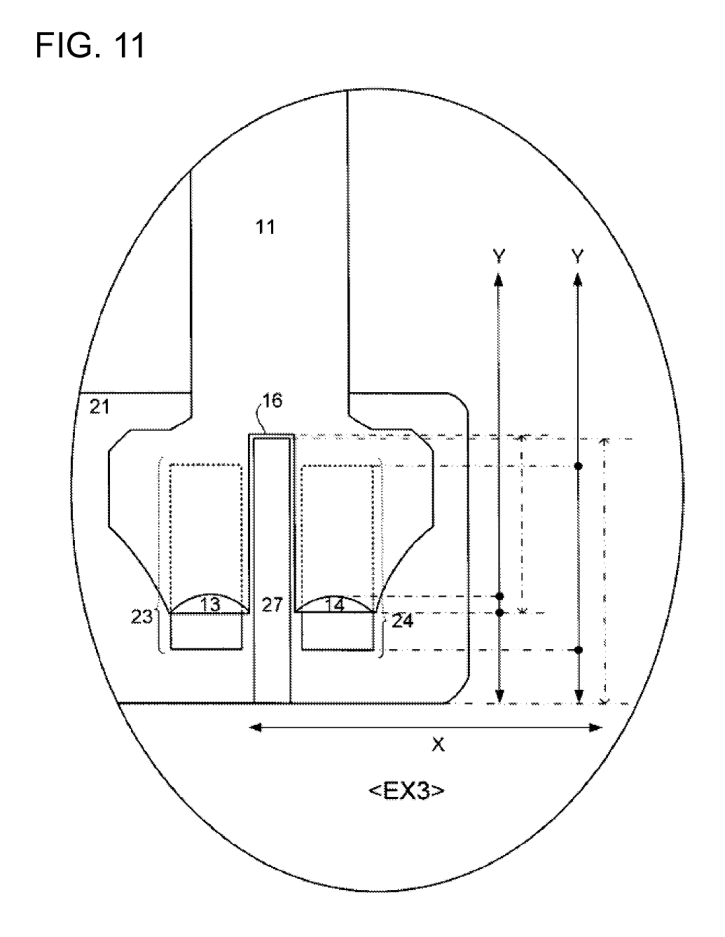

More specifically, it is preferable that the arrangement of the notch 16, the anode pad 13, and the cathode pad 14 on the light source FPC substrate 11 be as shown in FIG. 11. In the same manner as FIGS. 5 and 7 described in Embodiment 1, it is preferable that the two ends of the anode pad 13 and the two ends of the cathode pad 14 in the direction Y (see the black dots) be located inside of the opposite ends of the notch 16 in the direction Y (see respective one-dot lines in FIGS. 5 and 7). This way, the projection 27 engaging the notch 16 serves as a wall to separate the anode pad 13 and the cathode pad 14, which prevents the solder from making contact with both of the pads 13 and 14 so as to bridge over the two.

Further, it is preferable that the arrangement of the projection 27, the plus terminal 23, and the minus terminal 24 in the panel FPC substrate 21 be as shown in FIG. 11. More specifically, it is preferable that the two ends of the plus terminal 23 and the two ends of the minus terminal 24 in the direction Y (see black dots) on the panel FPC substrate 21 be located inside of the opposite ends of the projection 27 in the direction Y (see a two-dot chain line in FIG. 11). That is, it is preferable that the projection 27 be formed such that a side of the plus terminal 23 between the two end thereof in the direction Y entirely faces the projection 27 in the direction X and such that a side of the minus terminal 24 between the two ends thereof in the direction Y entirely faces the projection 27 in the direction X.

This way, the projection 27 serves as a wall to separate the plus terminal 23 and the minus terminal 24, which prevents the solder from making contact with both of the terminals 23 and 24 so as to bridge over the two.

It is preferable that the notch 16 in the light source FPC substrate 11 be a linear or polygonal notch. Also, it is preferable that the outer shape of the projection 27 engaging the notch 16 be the same shape as that of the notch 16.

With this configuration, when the single projection 27 engages the single notch 16, the light source FPC substrate 11 and the panel FPC substrate 21 are prevented from turning. (That is, the panel FPC substrate 21 and the light source FPC substrate 11 do not turn.) This means that even if the number of the projection 27 and the notch 16 is reduced to a minimum, the light source FPC substrate 11 and the panel FPC substrate 21 can be prevented from turning. Therefore, the respective areas for making the projection 27 and the notch 16 in the FPC substrates 11 and 21 are made smaller compared to a case where a number of projections 27 and notches 16 are formed in the FPC substrates 11 and 21.

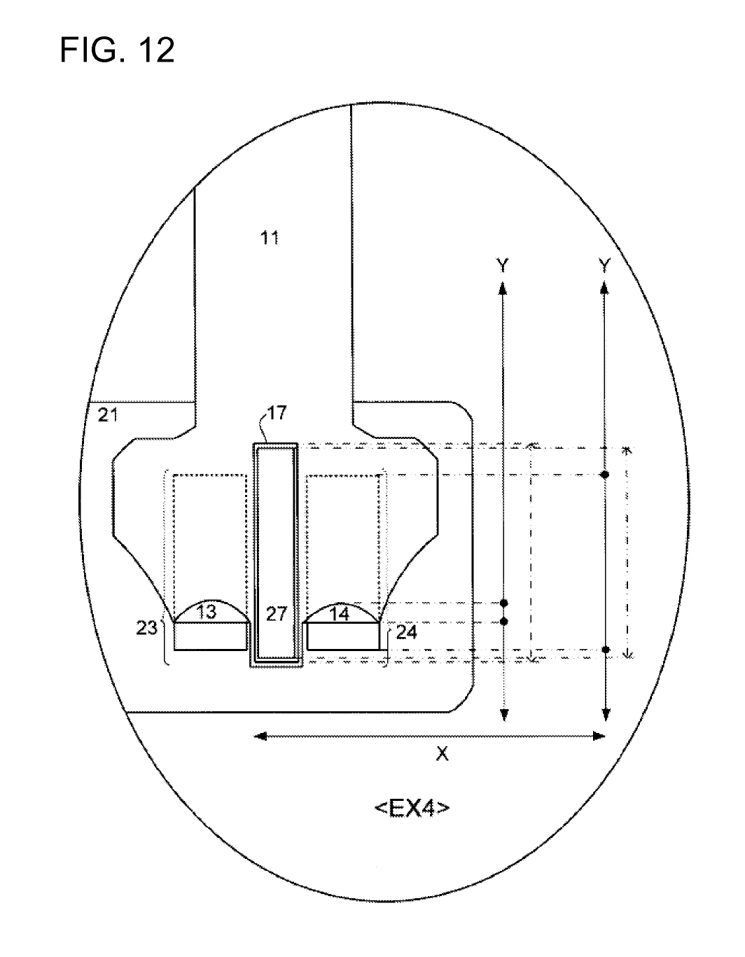

In the configuration described above, the notch 16 was provided in the light source FPC substrate 11 as a portion that makes contact with the projection 27 of the panel FPC substrate 21. However, the configuration is not limited to such. As shown in FIG. 12 (Example 4), for example, instead of the notch 16, the opening 17 may be formed in the light source FPC substrate 11. More specifically, a portion that makes contact with the projection 27 on the light source FPC substrate 11 may be an opening or a notch.

That is, as long as the portion in the light source FPC substrate 11 that makes contact with the projection 27 of the panel FPC substrate 21 prevents a displacement of the panel FPC substrate 21 and the light source FPC substrate 11, the portion may be the opening 17, the notch 16, or other structures (a projection, for example).

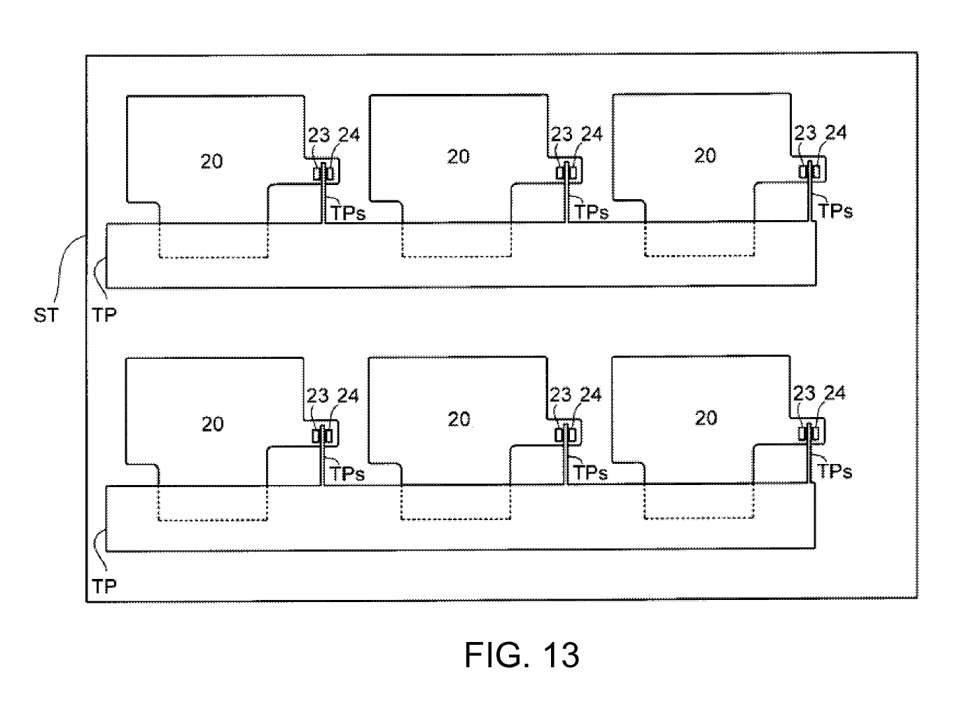

The projection 27 on the panel FPC substrate 21 can be formed through various methods. As shown in FIG. 4 and the like, the panel FPC substrate 21 may include a reinforcing tape (reinforcing member) TP, for example. Part of the reinforcing tape TP may serve as the material of the projection 27. The configuration in which the projection 27 is formed of such a reinforcing tape TP will be described below with reference to FIG. 13.

The panel FPC substrate 21 is made of a rolled substrate sheet (not shown). More specifically, as shown in FIG. 13, the rolled substrate sheet is cut to a size that can have a plurality of panel FPC substrates 21 arranged in a matrix of 3×2, for example. (Such a substrate sheet ST, which is used as a base of the panel FPC substrates 21 and has an area in which the plurality of the panel FPC substrates 21 are to be arranged in parallel, is referred to as a substrate sheet ST in a workable size.) On such a substrate sheet ST in a workable size, wiring and the terminals 23 and 24 are formed. (This forming step is referred to as patterning.)

One reinforcing tape TP is attached to the substrate sheet ST so as to bridge over areas 20 where three panel FPC substrates 21 are respectively to be formed, which forms one row of the matrix of 3×2. (Here, the respective areas 20 where the plurality of panel FPC substrate 21 are formed face the same direction, and an area to which the reinforcing tape TP is attached is part of the respective outer edges of the areas 20.) The reinforcing tape TP includes supplementary pieces TPs that extend in a direction intersecting with the longitudinal direction of the reinforcing tape TP (orthogonal direction, for example). The supplementary pieces TPs are designed to reach the respective areas between the plus terminals 23 and the minus terminals 24.

After the reinforcing tape TP is attached to a desired location on the areas 20 where the panel FPC substrates 21 are to be formed in the substrate sheet ST in a workable size, the substrate sheet ST is punched out with a die that is formed in the outer edge shape of the panel FPC substrate 21. (The reinforcing tape TP is attached to a desired position on the substrate sheet ST without misalignment by a not shown alignment unit.) As a result, six panel FPC substrates 21 are manufactured from one substrate sheet ST in a workable size.

In manufacturing the panel FPC substrate 21 as above, if the die for punching the areas 20 where the panel FPC substrates 21 are to be formed out of the substrate sheet ST and a metal mold for manufacturing the reinforcing tape TP that covers the areas 20 and the respective areas between the terminals 23 and 24 of the respective areas 20 are designed with a high degree of accuracy in advance, the reinforcing tape TP is arranged accurately between the terminals 23 and 24, respectively, and forms the projections 27.

Because the reinforcing tape TP forms the projection 27, as long as the step of attaching the reinforcing tape TP, which is a required step in the conventional configuration, is performed, it is not necessary to perform an extra step for forming the projection 27. Therefore, even though the panel FPC substrate 21 includes the projection 27, it does not make the process of manufacturing the panel FPC substrate 21 complex. In addition, because the reinforcing tape TP, which has been used conventionally, is utilized for the projection 27, the projection 27 can be formed with no additional material cost, thereby suppressing an increase in the cost.

The light source FPC substrate 11 can also be manufactured by various methods. As described above, the light source FPC substrates 11 may be manufactured by punching out the substrate sheet ST, which is used as a base of the light source FPC substrate 11 and has an area in which the plurality of light source FPC substrates 11 can be arranged in parallel, by using a die, for example. In manufacturing the light source FPC substrate 11 using such a die, by designing the die such that the openings 17 are formed at proper positions accurately, the light source FPC substrate 11 becomes less likely to be misaligned to the panel FPC substrate 21.

In the above-mentioned method of manufacturing the substrate set in which the plurality of FPC substrates 11 and 21 are at least partially overlapped, a stacking step described below is performed, but there is no special limitations on other steps.

That is, the method of manufacturing the substrate set needs to include stacking the light source FPC substrate 11, which has the notch 16 and the pads 13 and 14 disposed so as to sandwich the notch 16, and the panel FPC substrate 21, which has the terminals 23 and 24 to be in contact with the pads 13 and 14 and the projection 27 that is to engage the notch 16 and that is formed between the terminals 23 and 24 (stacking step).

### Embodiment 3

Embodiment 3 will be described below. Members having the same functions as those of the members described in Embodiments 1 and 2 are provided with the same reference characters, and descriptions thereof are omitted.

In Embodiments 1 and 2, the anode pad 13 and the cathode pad 14 are formed on part of the edge of the light source FPC substrate 11. This was to make it possible to dispose the anode pad 13 on the plus terminal 23 of the panel FPC substrate 21 such that the anode pad 13 is visible, and to dispose the cathode pad 14 on the minus terminal 24 such that the cathode pad 14 is visible. With this configuration, by applying the solder onto a border between the anode pad 13 and the plus terminal 23 and a border between the cathode pad 14 and the minus terminal 24 from a side in which the pads are exposed, for example, the electrical connection was established with ease.

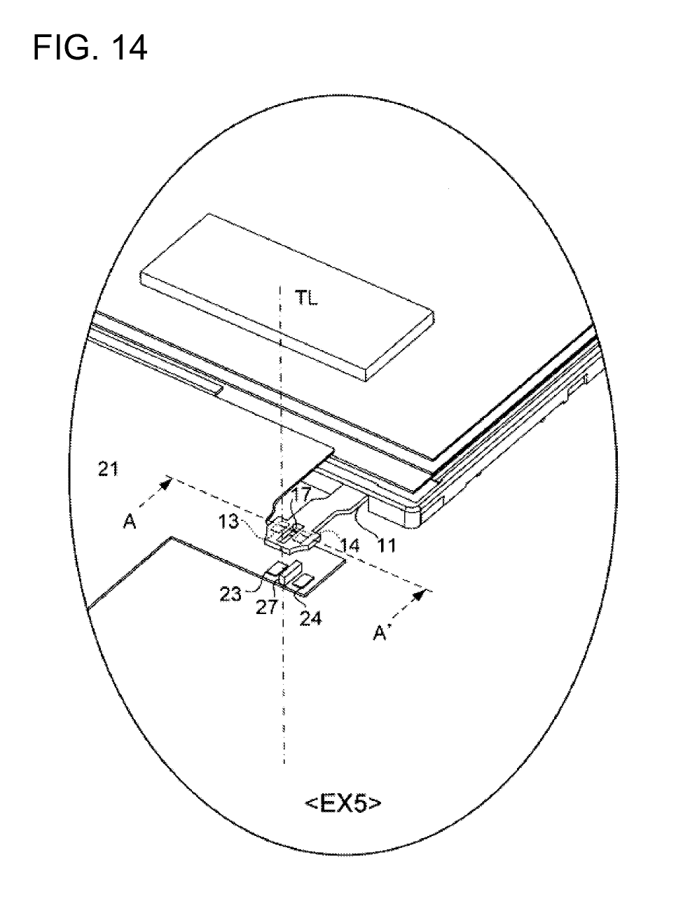

The respective locations of the anode pad 13 and the cathode pad 14, however, are not limited to part of the edge of the light source FPC substrate 11. As shown in FIG. 14 (Example 5), for example, the pads 13 and 14 may be formed on the surface of the light source FPC substrate 11 that directly faces the terminals 23 and 24 on the panel FPC substrate 21.

With this configuration, the anode pad 13 and the plus terminal 23 can be electrically connected, and the cathode pad 14 and the minus terminal 24 can be electrically connected by using a constant heat tool TL and extra solder (not shown). More specifically, first, the extra solder is applied to at least one of the anode pad 13 and the plus terminal 23, and to at least one of the cathode pad 14 and the minus terminal 24.

Thereafter, as shown in the perspective view in FIG. 14, the light source FPC substrate 11 included in the backlight unit 49 is placed above the panel FPC substrate 21 included in the liquid crystal display panel 59. Thereafter, the opening 17 of the light source FPC substrate 11 engages the projection 27 of the panel FPC substrate 21. This way, when the panel FPC substrate 21 and the light source FPC substrate 11 overlap each other, the anode pad 13 of the light source FPC substrate 11 overlaps the plus terminal 23 of the panel FPC substrate 21, and the cathode pad 14 of the light source FPC substrate 11 overlaps the minus terminal 24 of the panel FPC substrate 21.

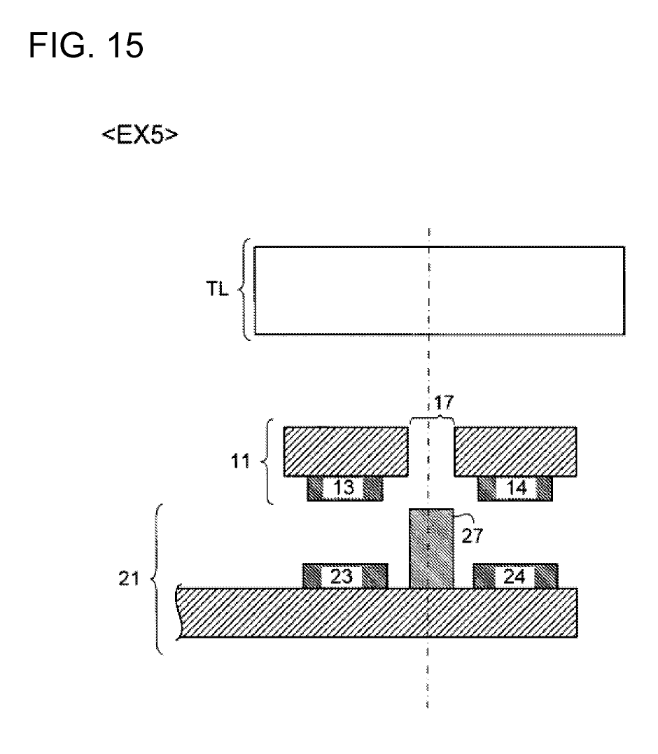

Thereafter, as shown in FIGS. 14 and 15 (a cross-sectional view along the line A-A′ indicated by arrows in FIG. 14), the constant heat tool TL is placed on the rear surface of the substrate, which is opposite to the surface on which the anode pad 13 and the cathode pad 14 are formed. Then, heat from the constant heat tool TL is transmitted to the light source FPC substrate 11, and then to the anode pad 13 and the cathode pad 14.

Because of this heat conduction, the extra solder that is attached to at least one of the anode pad 13 and the plus terminal 23, and the extra solder that is attached to at least one of the cathode pad 14 and the minus terminal 24 start melting. Pressure from the constant heat tool TL is also applied to the FPC substrates 11 and 21. As a result, the anode pad 13 and the plus terminal 23 are electrically connected by the solder, and the cathode pad 14 and the minus terminal 24 are also electrically connected by the solder. (That is, the pads and the terminals are bonded by thermo-compression.)

In this thermo-compression bonding, the melted extra solder may overflow due to the pressure from the constant heat tool TL. However, the projection 27 blocks the melted extra solder. More specifically, the projection 27 blocks the extra solder that connects the anode pad 13 to the plus terminal 23 from reaching the cathode pad 14 and the minus terminal 24. Therefore, as in Embodiments 1 and 2, the electrical connection between the FPC substrates 11 and 21 is reliably achieved with ease. (In other words, the effects achieved with the substrate set described in Embodiments 1 and 2 are also achieved with the substrate set described in Embodiment 3.)

The extra solder here is the same as an extra solder used for mounting various parts (discrete semiconductors) on the light source FPC substrate 11 and the panel FPC substrate 21. That is, when the extra solder is applied to the FPC substrates 11 and 21 by screen printing so as to be used for mounting the discrete semiconductors thereon, the extra solder is to be applied to at least one of the pads and the terminals. Thus, because it does not require an additional step of applying the extra solder for the electrical connection between the pad 13 and the terminal 23 and between the pad 14 and the terminal 24, separately from the step of applying the solder for mounting the discrete semiconductors, the manufacturing process does not become complex.

When the FPC substrates 11 and 12 are placed in a reflow oven (heating furnace), for example, so as to melt the extra solder for mounting discrete semiconductors on the FPC substrates 11 and 21, the extra solder that is applied to at least one of the pads 13 and 14 and the terminals 23 and 24 is also melted. The melted extra solder is further melted by the constant heat tool TL, thereby connecting (soldering) the pads 13 to the terminal 23, and the pad 14 to the terminal 24. In order to improve the soldering performance, flux may be applied to the solder.

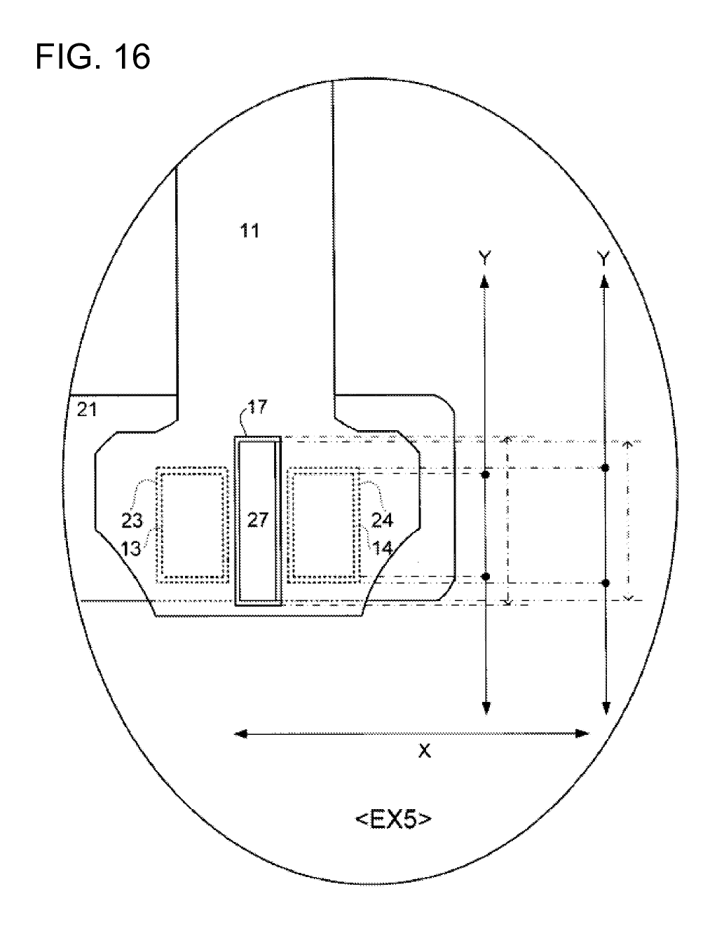

When the light source FPC substrate 11 and the panel FPC substrate 21 are electrically connected using the constant heat tool TL as described above, it is also preferable that the arrangement of the opening 17, the anode pad 13, and the cathode pad 14 on the light source FPC substrate 11 be as shown in a plan view in FIG. 16.

That is, in the same manner as Example 4, it is preferable that the two ends of the anode pad 13 and the two ends of the cathode pad 14 (see black dots) in the direction Y be located inside of the opposite ends of the opening 17 in the direction Y (see a one-dot chain line in FIG. 16). Further, it is preferable that the two ends of the plus terminal 23 and the two ends of the minus terminal 24 (see black dots) on the panel FPC substrate 21 in the direction Y be located inside of the opposite ends of the projection 27 in the direction Y (see a two-dot chain line in FIG. 16).

This way, the projection 27 engaging the opening 17 serves as a wall to separate the anode pad 13 and the cathode pad 14, which prevents the solder from making contact with both of the pads 13 and 14 so as to bridge over the two. Also, the projection 27 on the panel FPC substrate 21 serves as a wall to separate the plus terminal 23 and the minus terminal 24, which prevents the solder from making contact with both of the terminals 23 and 24 so as to bridge over the two.

### Embodiment 4

Embodiment 4 will be described below. Members having the same functions as those of the members described in Embodiments 1 to 3 are provided with the same reference characters, and descriptions thereof are omitted.

In Embodiments 1 to 3, the configuration in which two pads, which are the anode pad 13 and the cathode pad 14 on the light source FPC substrate 11, and two terminals, which are the plus terminal 23 and the minus terminal 24 on the panel FPC substrate 21, are electrically connected to each other, respectively, was described as an example. However, it may also be configured such that a single pad (first contact portion, first contact piece) 15 is provided on the light source FPC substrate 11, and a single terminal (second contact portion, second contact piece) 25 is provided on the panel FPC substrate 21.

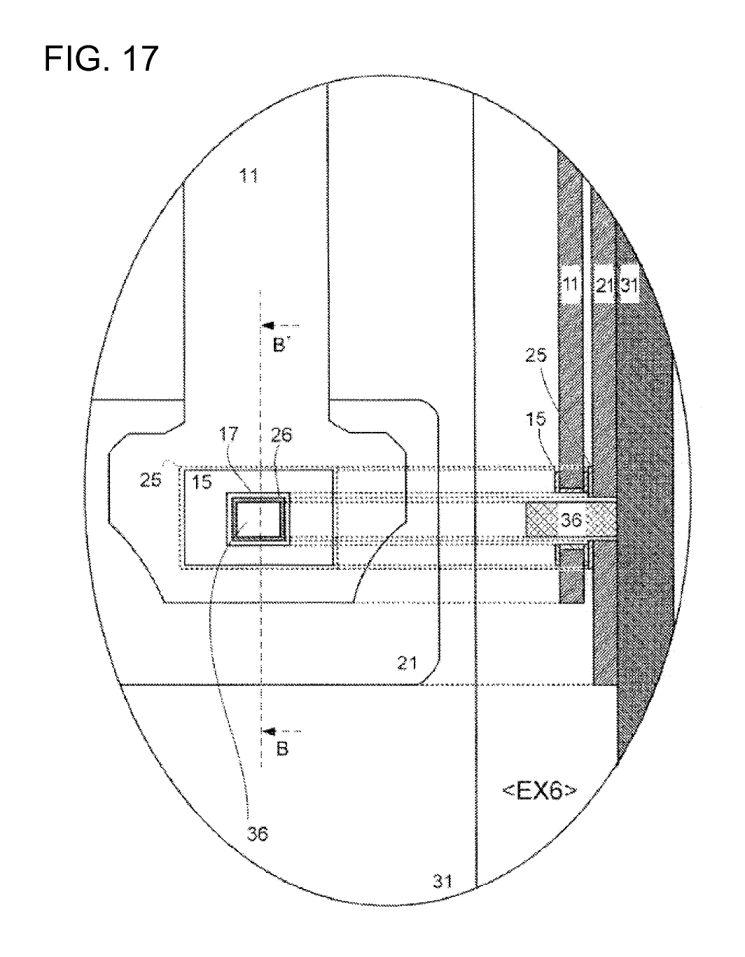

As shown in a two-side view in FIG. 17 (a plan view and a cross-sectional view along the line B-B′ indicated by arrows in the plan view), for example, the pad 15 on the light source FPC substrate 11 may have the opening 17, the terminal 25 on the panel FPC substrate 21 may have the opening 26, and the alignment pin 36 of the jig 31 may engage the openings 17 and 26. This way, when the solder is injected into a gap between the alignment pin 36 and the openings 17 and 26, the electrical connection between the pad 15 and the terminal 25 is established. (The liquid crystal display device 69 and the like shown in FIG. 17 are referred to as Example 6.)

That is, when the light source FPC substrate 11 has the opening 17 and the pad 15 disposed so as to sandwich (enclose) the opening 17, and the panel FPC substrate 21 has the terminal 25 to be in contact with the pad 15 and the opening 26 that is sandwiched by the terminal 25, the stacked FPC substrates 11 and 21 are electrically connected without using connectors or the like.

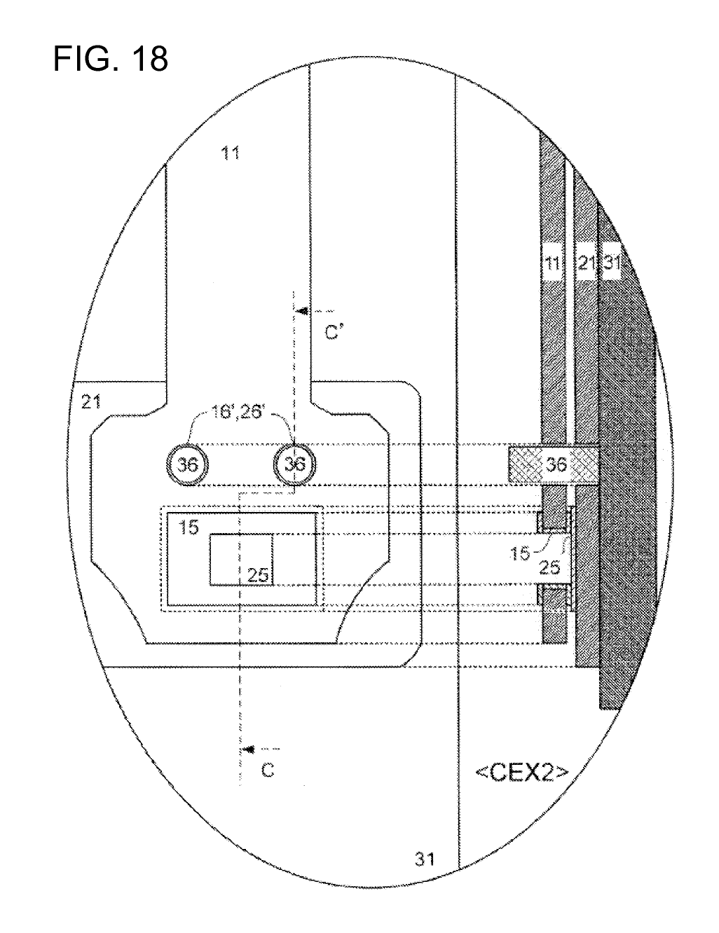

In addition, as shown in a two-side view in FIG. 18 (a plan view and a cross-sectional view along the line C-C′ indicated by arrows in the plan view), the area of the light source FPC substrate 11 and the area of the panel FPC substrate 21 in Example 6 shown in FIG. 17 become smaller compared to Comparative Example 2 (CEX2) where the alignment openings 16′ are formed in the light source FPC substrate 11 at positions remote from the pad 15, and where the alignment openings 16′ and 26′ are formed in the panel FPC substrate 21 at positions remote from the terminal 25. That is, in a manner similar to Embodiments 1 to 3, the unutilized areas in the FPC substrates 11 and 21 are effectively utilized, thereby reducing the areas of the FPC substrates 11 and 21.

### Other Embodiments

The present invention is not limited to the above-mentioned embodiments, and various modifications can be made without departing from the scope of the present invention.

As shown in FIGS. 5, 7, 11, 12, 16, for example, the two ends of the pad 13 and the two ends of the pad 14 in the direction Y (first intersecting direction) on the substrate plane of the light source FPC substrate 11 are located inside the opposite ends of the notch 16 or inside the opposite ends of the opening 17 in the direction Y. Also, the two ends of the terminal 23 and the two ends of the terminal 24 in the direction Y (second intersecting direction) on the panel FPC substrate 21 are located inside the opposite ends of the opening 26 or inside the opposite ends of the projection 27 in the direction Y.

However, the configuration is not limited to such. On the substrate plane of the light source FPC substrate 11, for example, at least one of the two ends of the pad 13 and the two ends of the pad 14 in the direction Y may be located inside the opposite ends of the notch 16 or inside the opposite ends of the opening 17 in the direction Y. Also, at least one of the two ends of the terminal 23 and the two ends of the terminal 24 in the direction Y on the panel FPC substrate 21 may be located inside the opposite ends of the opening 26 or inside the opposite ends of the projection 27 in the direction Y. This configuration can also prevent the formation of the solder bridge.

It is preferable that the alignment pin 36 of the jig 31 and the projection 27 formed on the panel FPC substrate 21 be made of a material with an insulating property. For such a material, a polyimide resin or a polyethylene terephthalate resin can be used, for example. (The reinforcing tape TP may be a polyimide tape or a polyethylene terephthalate tape, for example.)

The upper temperature limit of a polyimide resin is lower than that of a polyethylene terephthalate resin. Therefore, when soldering is performed using the reflow oven as described in Embodiment 3, it is preferable that the projection 27 and the like be made of a polyimide resin, and when a soldering iron is used for soldering, it is preferable that the projection 27 and the like be made of a polyethylene terephthalate resin. This is because the temperature of the soldering iron is higher than the temperature in the reflow oven. That is, it is preferable that the material for the projection 27 and the like be changed according to the method of electrically connecting the FPC substrates 11 and 21.

### DESCRIPTION OF REFERENCE CHARACTERS

11 light source FPC substrate (first substrate)
13 anode pad (first contact portion, first contact piece)
14 cathode pad (first contact portion, first contact piece)
15 pad (first contact portion, first contact piece)
16 notch (first gap portion)
17 opening (first gap portion)
21 panel FPC substrate (second substrate)
23 plus terminal (second contact portion, second contact piece)
24 minus terminal (second contact portion, second contact piece)
25 terminal (second contact portion, second contact piece)
26 opening (second gap portion)
27 projection
31 jig
36 alignment pin
41 backlight chassis
49 backlight unit (illumination device)
59 liquid crystal display panel (display panel)
69 liquid crystal display device (display device, electronic device)
X direction in which pads are arranged in parallel or a direction in which terminals are arranged in parallel
Y direction that intersects with direction X

1. A substrate set including a plurality of substrates that are stacked, comprising:
a first substrate that has a first gap portion and a first contact portion, the first contact portion being disposed so as to sandwich the first gap portion; and
a second substrate that has a second contact portion and a second gap portion, the second contact portion being provided to be in contact with the first contact portion, the second gap portion being sandwiched by the second contact portion.

2. The substrate set according to claim 1, wherein the first contact portion is constituted of a group of first contact pieces that are separated from each other, and the first contact pieces are disposed so as to be divided by the first gap portion, and
wherein the second contact portion is constituted of a group of second contact pieces that are separated from each other, and the second contact pieces are disposed so as to be divided by the second gap portion.

3. The substrate set according to claim 2, wherein, when a direction that intersects with a direction in which the first contact pieces are arranged in parallel on a substrate plane of the first substrate is defined as a first intersecting direction,
at least one of two ends of the first contact piece in the first intersecting direction is located inside opposite ends of the first gap portion in the first intersecting direction.

4. The substrate set according to claim 2, wherein, when a direction that intersects with a direction in which the second contact pieces are arranged in parallel on a substrate plane of the second substrate is defined as a second intersecting direction,
at least one of two ends of the second contact piece in the second intersecting direction is located inside opposite ends of the second gap portion in the second intersecting direction.

5. The substrate set according to claim 1, wherein the first gap portion and the second cap portion are linear or polygonal openings, or linear or polygonal notches.

6. A substrate set including a plurality of substrates that are stacked, comprising:
a first substrate that has a first gap portion and a first contact portion, the first contact portion being disposed so as to sandwich the first gap portion; and
a second substrate that has a second contact portion and a projection, the second contact portion being provided to be in contact with the first contact portion, the projection being provided so as to engage the first gap portion and so as to be sandwiched by the second contact portion.

7. The substrate set according to claim 6, wherein the first contact portion is constituted of a group of first contact pieces that are separated from each other, and the first contact pieces are disposed so as to be divided by the first gap portion, and
wherein the second contact portion is constituted of a group of second contact pieces that are separated from each other, and the second contact pieces are disposed so as to be divided by the projection.

8. The substrate set according to claim 7, wherein, when a direction that intersects with a direction in which the first contact pieces are arranged in parallel on a substrate plane of the first substrate is defined as a first intersecting direction,
at least one of two ends of the first contact piece in the first intersecting direction is located inside opposite ends of the first gap portion in the first intersecting direction.

9. The substrate set according to claim 7, wherein, when a direction that intersects with a direction in which the second contact pieces are arranged in parallel on a substrate plane of the second substrate is defined as a second intersecting direction,
at least one of two ends of the second contact piece in the second intersecting direction is located inside opposite ends of the projection in the second intersecting direction.

10. The substrate set according to claim 6, wherein the first gap portion is a linear or polygonal opening or a linear or polygonal notch, and
wherein an outer shape of the projection that engages the first gap portion coincides with a shape of the first gap portion.

11. The substrate set according to claim 6, wherein the projection is made of an insulating member.

12. The substrate set according to claim 6, wherein the projection is a part of a reinforcing member included in the second substrate.

13. The substrate set according to claim 12, wherein the reinforcing member is attached to a substrate sheet that is used as a base of the second substrate and that has an area for a plurality of second substrates to be arranged in parallel, and
wherein the reinforcing member overlaps at least part of an edge of the second substrate in the substrate sheet, and is bridged over the plurality of second substrates in the substrate sheet.

14. An electronic device including the substrate set according to claim 1.

15. A method of manufacturing a substrate set in which a plurality of substrates are at least partially overlapped with each other by using a jig, wherein the jig includes an alignment pin, and
wherein the method of manufacturing a substrate set comprises:
placing, on the jig, a first substrate that has a first gap portion that engages the alignment pin and a first contact portion disposed so as to sandwich the first gap portion, and
stacking the first substrate and a second substrate that has a second gap portion and a second contact portion, the second gap portion engaging the alignment pin, the second contact portion being disposed so as to sandwich the second gap portion and so as to cover the first contact portion.

16. A method of manufacturing a substrate set in which a plurality of substrates are at least partially overlapped with each other, comprising
stacking a first substrate and a second substrate, the first substrate having a first gap portion and a first contact portion disposed so as to sandwich the first gap portion, the second substrate having: a second contact portion disposed so as to be in contact with the first contact portion; and a projection that engages the first gap portion and that is disposed so as to be sandwiched by the second contact portion.
